(19) United States
(12) Patent Application Publication
(10) Pub. No.: US 2025/0078903 A1
(43) Pub. Date: Mar. 6, 2025

(54) DISCHARGING AN ACCESS DEVICE IN A MEMORY DEVICE

(71) Applicant: Micron Technology, Inc., Boise, ID (US)

(72) Inventors: Huy T. Vo, Boise, ID (US); Eric Carman, Boise, ID (US); Kamal M. Karda, Boise, ID (US)

(21) Appl. No.: 18/790,372

(22) Filed: Jul. 31, 2024

Related U.S. Application Data
(60) Provisional application No. 63/535,415, filed on Aug. 30, 2023.

(51) Int. Cl. G11C 11/4074; G11C 11/4091; H10B 12/00

(52) U.S. Cl. CPC G11C 11/4074; G11C 11/4091; H10B 12/30

(57) ABSTRACT

Systems, methods, and apparatus are provided for discharging an access device in a memory device. An example structure includes a memory device having a local sense line and a bleeder device coupled to the local sense line and a bleeder supply. The memory device can also include a sense line multiplexor coupled to the local sense line and a global sense line, and a sense amplifier coupled to the global sense line. The sense amplifier can be configured to sense and latch a voltage of the global sense line in response to the memory device receiving a command. The memory device can further include a plurality of access devices coupled to the local sense line, a plurality of capacitors coupled to the plurality of access devices, and a plate voltage supply, separate from the bleeder supply, coupled to the plurality of capacitors.

### PRIORITY INFORMATION

This application claims the benefit of U.S. Provisional Application No. 63/535,415, filed on Aug. 30, 2023, the contents of which are incorporated herein by reference.

### TECHNICAL FIELD

The present disclosure relates generally to memory devices, and more particularly, to discharging an access device in a memory device.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by a channel region. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a shared sense line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1 is a schematic illustration of a vertical three dimensional (3D) memory in accordance with a number of embodiments of the present disclosure.

FIG. 2 is a perspective view illustrating a portion of a shared vertical sense line for semiconductor devices in accordance with a number of embodiments of the present disclosure.

FIGS. 3A-3B illustrate a portion of a shared vertical sense line for semiconductor devices in accordance with a number of embodiments of the present disclosure.

FIG. 4 is a cross-sectional view of an array of memory cells in accordance with a number of embodiments of the present disclosure.

FIG. 5 illustrates an example method for discharging an access device in a memory device in accordance with a number of embodiments of the present disclosure.

FIG. 6 is a block diagram of an apparatus in the form of a computing system including a memory device in accordance with a number of embodiments of the present disclosure.

### DETAILED DESCRIPTION

Embodiments of the present disclosure describe discharging an access device in a memory device. A memory device can include a bleeder device that can be coupled to a local sense line and a bleeder supply. A sense line multiplexor can be coupled to the local sense line and a global sense line. A sense amplifier can be coupled to the global sense line and can be configured to sense and latch a voltage of the global sense line in response to the memory device receiving a command. A plurality of access devices can be coupled to the local sense line. A plurality of capacitors can be coupled to the plurality of access devices. A bias voltage supply, which is separate from the bleeder supply, can be coupled to the plurality of capacitors.

A thin film transistor can be implemented in three-dimensional (3D) dynamic random access memory (DRAM) and emerging memory in order to increase memory array efficiency and to reduce die sizes. In previous approaches, since the architecture of 3D memory makes grounding the transistor very difficult, the body of the transistor can be floating (e.g., not grounded) once it is implemented into a 3D memory. For instance, implementation of a thin film transistor with a floating body can result in increased memory cell leakage and/or increased voltage threshold (Vt) variation.

In contrast, embodiments of the present disclosure can provide a means to discharge the floating body of the thin film transistor by implementing a variable pre-charge voltage level for a local sense line, activating and deactivating a global sense line multiplexor and a local sense line pre-charge device, such as a bleeder device, before the voltage threshold compensation duration and after a sense amplifier that is coupled to the global sense line is activated. The pre-charge voltage level of the local sense line can be controlled via the bleeder device and can be reduced from a current cell plate voltage to a lower voltage such as a ground voltage, a positive voltage that is less than 1 volt (V) and greater than 0V, or a negative voltage that is greater than −1V and less than 0V.

The current approach as described herein can provide a means to discharge a floating body of a transistor (e.g., a thin film transistor) during an off-state (e.g., an idle-state) of the transistor. The floating body of a transistor, such as a thin film transistor, can be discharged by maintaining the local sense line at a lower voltage and thereby can provide a path to discharge the floating body of the transistor through a p-n junction of the transistor. As used herein, the term “p-n junction” refers to the boundary between a p-type semiconductor material or intrinsic semiconductor material, and a n-type semiconductor material within the transistor. For example, maintaining the local sense line at a lower voltage reduces a barrier for storing holes in the floating body of the transistor which causes some holes to be released from the floating body. As used herein, the term “holes” refers to the absence of an electron from a full valence band. The movement of holes refers to a movement of electrons that leaves holes in the different locations where the electron moved from. This indicates a movement of electrons which indicates a movement of current.

In some embodiments, setting a sense line voltage of 0.1 V can allow current to be discharged through the p-n junction coupled to the sense line and setting a storage node (e.g., capacitor) to 0 V can allow current to be discharged through the p-n junction coupled to a storage node (e.g., capacitor). In some embodiments, the floating body of the transistor can discharge the current through the p-n junction coupled to the sense line but not the p-n junction coupled to the storage node. In other embodiments, the floating body of the transistor can discharge the current through the p-n junction coupled to the storage node but not the p-n junction coupled to the sense line. In other embodiments, the floating body can be discharged from both the p-n junction coupled to the sense line and the p-n junction coupled to the storage node. Discharging the floating body of the transistor during a given state (e.g., an off-state) of a transistor in accordance with embodiments of this disclosure can result in a reduction of channel leakage in the transistor and/or less Vt variation of the transistor.

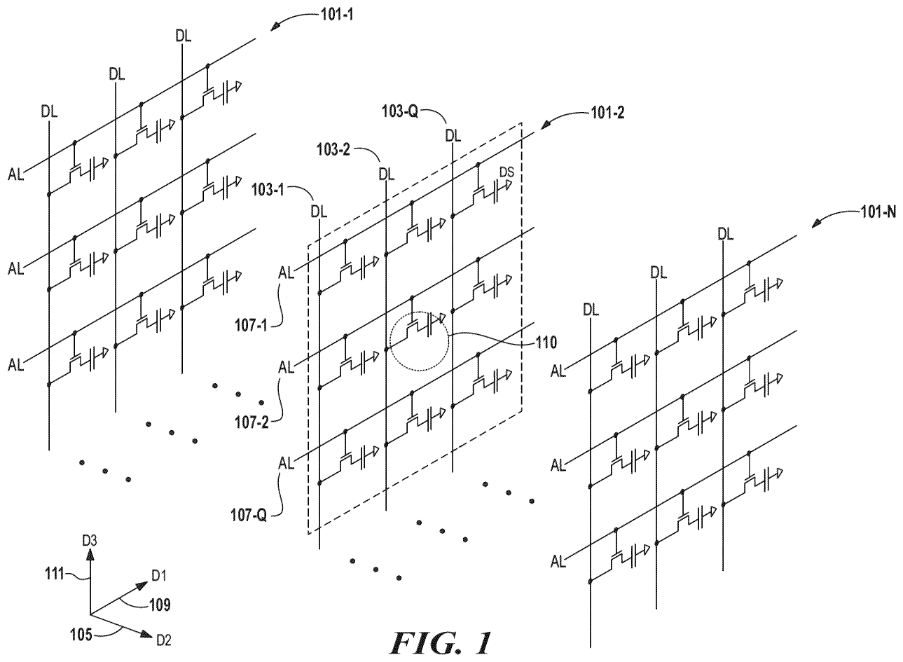

FIG. 1 is a block diagram of an apparatus in accordance with a number of embodiments of the present disclosure. FIG. 1 illustrates a circuit diagram showing a cell array of a three dimensional (3D) semiconductor memory device according to embodiments of the present disclosure. FIG. 1 illustrates a cell array may have a plurality of sub cell arrays 101-1, 101-2, . . . , 101-N. The plurality of sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to a word lines). Also, each of the sub cell arrays, e.g., sub cell array 101-2, may include a plurality of shared sense lines 103-1, 103-2, . . . , 103-Q (which also may be referred to as bit lines, data lines, or digit lines). In FIG. 1, the access lines 107-1, 107-2, . . . , 107-Q are illustrated extending in a first direction (D1) 109 and the shared sense lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the shared sense lines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each shared sense line 103-1, 103-2, . . . , 103-Q. Memory cells may be written to, or read from, using the access lines 107-1, 107-2, . . . , 107-Q and shared sense lines 103-1, 103-2, . . . , 103-Q. The access lines 107-1, 107-2, . . . , 107-Q may conductively interconnect memory cells along horizontal rows of each sub cell array 101-1, 101-2, . . . , 101-N, and the sense lines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one shared sense line, e.g., 103-2. Each memory cell may be uniquely addressed through a combination of an access line 107-1, 107-2, . . . , 107-Q and a shared sense line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The shared sense lines 103-1, 103-2, . . . , 103-Q may be or include conductive patterns (e.g., metal lines) extending in a vertical direction with respect to the substrate, e.g., in a third direction (D3) 111. The shared sense lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., a first source/drain region of an access device, e.g., transistor, of the memory cell 110 may be connected to a shared sense line, e.g., 103-2. Each of the memory cells, e.g., memory cell 110, may be connected to a storage node, e.g., capacitor. A second conductive node, e.g., a second source/drain region of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to shared sense line, e.g., 103-2, and the other may be connected to a storage node.

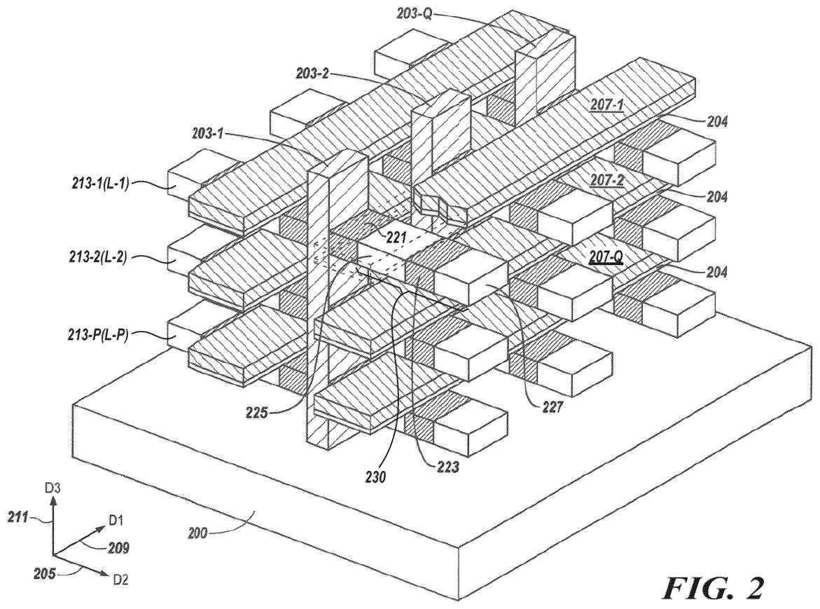

FIG. 2 illustrates a perspective view showing a three dimensional (3D) semiconductor memory device, e.g., a portion of a sub cell array 101-2 shown in FIG. 1 as a vertically oriented stack of memory cells in an array, according to some embodiments of the present disclosure. FIG. 2 illustrates a perspective view showing unit cell, e.g., memory cell 110 shown in FIG. 1, of the 3D semiconductor memory device shown in FIG. 2.

As shown in FIG. 2, a substrate 200 may have formed thereon one of the plurality of sub cell arrays, e.g., 101-2, described in connection with FIG. 1. For example, the substrate 200 may be or include a silicon substrate, a germanium substrate, or a silicon-germanium substrate, etc. Embodiments, however, are not limited to these examples.

As shown in the example embodiment of FIG. 2, the substrate 200 may have fabricated thereon a vertically oriented stack of memory cells, e.g., memory cell 110 in FIG. 1, extending in a vertical direction, e.g., third direction (D3) 111. According to some embodiments, the vertically oriented stack of memory cells may be fabricated such that each memory cell, e.g., memory cell 110 in FIG. 1, is formed on plurality of vertical levels, e.g., a first level (L-1), a second level (L-2), and a Pth level (L-P). The repeating, vertical levels, L-1, L-2, and L-P, may be arranged, e.g., “stacked”, in a vertical direction, e.g., third direction (D3) 111 shown in FIG. 1. Each of the repeating, vertical levels, L-1, L-2, and L-P may include a plurality of discrete components, e.g., regions, of the horizontally oriented access devices, e.g., transistors, and storage nodes, e.g., capacitors, including access line 107-1, 107-2, . . . , 107-Q connections and shared sense line 103-1, 103-2, . . . , 103-Q connections. The plurality of discrete components of the horizontally oriented access devices 230, e.g., transistors, may be formed in a plurality of iterations of vertically, repeating layers within each level, and may extend horizontally in the second direction (D2) 205, analogous to second direction (D2) 105 shown in FIG. 1.

The plurality of discrete components of the horizontally oriented access devices 230, e.g., transistors, may include a first source/drain region 221 and a second source/drain region 223 separated by a channel region 225, extending laterally in the second direction (D2) 205, and formed in a body of the access devices. In some embodiments, the channel region 225 may include silicon, germanium, silicon-germanium, and/or indium gallium zinc oxide (IGZO). In some embodiments, the first and the second source/drain regions, 221 and 223, can include an n-type dopant region formed in a p-type doped body of the access device to form an n-type conductivity transistor. In some embodiments, the first and the second source/drain regions, 221 and 223, may include a p-type dopant formed within an n-type doped body or undoped intrinsic body to the access device to form a p-type conductivity transistor. By way of example, and not by way of limitation, the n-type dopant may include Phosphorous (P) atoms and the p-type dopant may include atoms of Boron (B) formed in an oppositely doped body region of polysilicon semiconductor material. Embodiments, however, are not limited to these examples.

The storage node 227, e.g., capacitor, may be connected to one respective end of the access device. As shown in FIG. 2, the storage node 227, e.g., capacitor, may be connected to the second source/drain region 223 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1, may similarly extend in the second direction (D2) 205, analogous to second direction (D2) 105 shown in FIG. 1.

As shown in FIG. 2 a plurality of horizontally oriented access lines 207-1, 207-2, . . . , 207-Q extend in the first direction (D1) 209, analogous to the first direction (D1) 109 in FIG. 1. The plurality of horizontally oriented access lines 207-1, 207-2, . . . , 207-Q may be analogous to the access lines 107-1, 107-2, . . . , 107-Q shown in FIG. 1. The plurality of horizontally oriented access lines 207-1, 207-2, . . . , 207-Q may be arranged, e.g., “stacked”, along the third direction (D3) 211. The plurality of horizontally oriented access lines 207-1, 207-2, . . . , 207-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

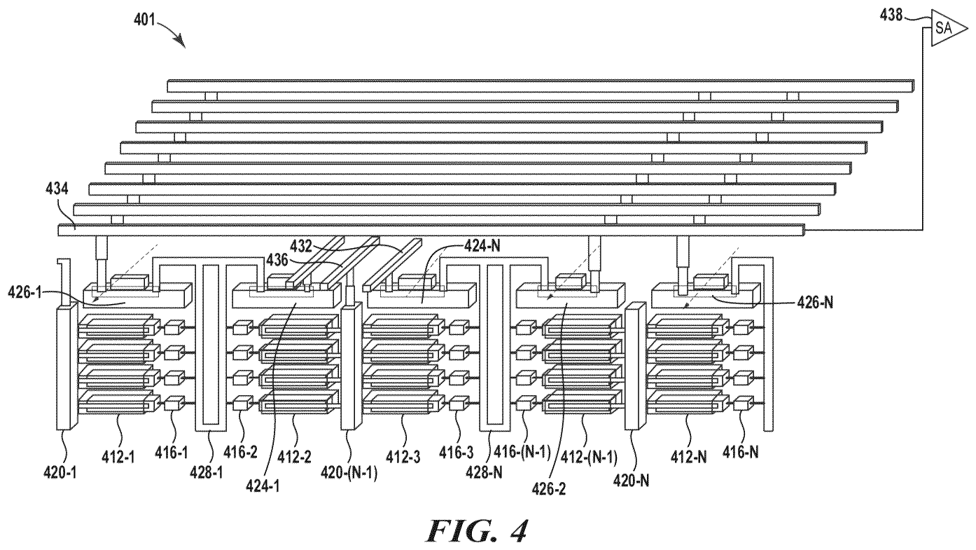

Among each of the vertical levels, (L-1) 213-1, (L-2) 213-2, and (L-P) 213-P, the horizontally oriented memory cells, e.g., memory cell 110 in FIG. 1, may be spaced apart from one another horizontally in the first direction (D1) 209. However, as described in more detail below in connection with FIG. 4 et. seq., the plurality of discrete components to the horizontally oriented access devices 230, e.g., first source/drain region 221 and second source/drain region 223 separated by a channel region 225, extending laterally in the second direction (D2) 205, and the plurality of horizontally oriented access lines 207-1, 207-2, . . . , 207-Q extending laterally in the first direction (D1) 209, may be formed within different vertical layers within each level. For example, the plurality of horizontally oriented access lines 207-1, 207-2, . . . , 207-Q, extending in the first direction (D1) 209, may be formed on a top surface opposing and electrically coupled to the channel regions 225, separated therefrom by a gate dielectric 204, and orthogonal to horizontally oriented access devices 230, e.g., transistors, extending in laterally in the second direction (D2) 205. In some embodiments, the plurality of horizontally oriented access lines 207-1, 207-2, . . . , 207-Q, extending in the first direction (D1) 209 are formed in a higher vertical layer, farther from the substrate 200, within a level, e.g., within level (L-1), than a layer in which the discrete components, e.g., first source/drain region 221 and second source/drain region 223 separated by a channel region 225, of the horizontally oriented access device are formed.

As shown in the example embodiment of FIG. 2, the shared sense lines, 203-1, 203-2, . . . , 203-Q, extend in a vertical direction with respect to the substrate 200, e.g., in a third direction (D3) 211. Further, as shown in FIG. 2, the shared sense lines, 203-1, 203-2, . . . , 203-Q, in one sub cell array, e.g., sub cell array 101-2 in FIG. 1, may be spaced apart from each other in the first direction (D1) 209. The shared sense lines, 203-1, 203-2, . . . , 203-Q, may be provided, extending vertically relative to the substrate 200 in the third direction (D3) 211 in vertical alignment with source/drain regions to serve as first source/drain regions 221 or, as shown, be vertically adjacent first source/drain regions 221 for each of the horizontally oriented access devices 230, e.g., transistors, extending laterally in the second direction (D2) 205, but adjacent to each other on a level 213, e.g., first level (L-1) 213-1, in the first direction (D1) 209. Each of the shared sense lines, 203-1, 203-2, . . . , 203-Q, may vertically extend, in the third direction (D3), adjacent first source/drain regions 221 of respective ones of the plurality of horizontally oriented access devices 230, e.g., transistors, that are vertically stacked. In some embodiments, the plurality of shared vertically oriented sense lines 203-1, 203-2, . . . , 203-Q, extending in the third direction (D3) 211, may be connected to side surfaces of the first source/drain regions 221 directly and/or through additional contacts including metal silicides.

For example, and as shown in more detail in FIG. 2, a first one of the shared vertically extending sense lines, e.g., 203-1, may be adjacent a first source/drain region 221 of a first one of the horizontally oriented access devices 230, e.g., transistors, in the first level (L-1) 213-1, a first source/drain region 221 of a first one of the horizontally oriented access devices 230, e.g., transistors, in the second level (L-2) 213-2, and a first source/drain region 221 a first one of the horizontally oriented access devices 230, e.g., transistors, in the Pth level (L-P) 213-P, etc. Similarly, a second one of the shared vertically extending sense lines, e.g., 203-2, may be adjacent a first source/drain region 221 of a second one of the horizontally oriented access devices 230, e.g., transistors, in the first level (L-1) 213-1, spaced apart from the first one of horizontally oriented access devices 230, e.g., transistors, in the first level (L-1) 213-1 in the first direction (D1) 209. And the second one of the shared vertically extending sense lines, e.g., 203-2, may be adjacent a first source/drain region 221 of a second one of the horizontally oriented access devices 230, e.g., transistors, in the second level (L-2) 213-2, and a first source/drain region 221 of a second one of the horizontally oriented access devices 230, e.g., transistors, in the Pth level (L-P) 213-P, etc. Embodiments are not limited to a particular number of levels.

The shared vertically extending sense lines, 203-1, 203-2, . . . , 203-Q, may include a conductive material, such as, for example, one of a doped semiconductor material, a conductive metal nitride, metal, and/or a metal-semiconductor compound. The shared sense lines, 203-1, 203-2, . . . , 203-Q, may correspond to shared sense lines (DL) described in connection with FIG. 1.

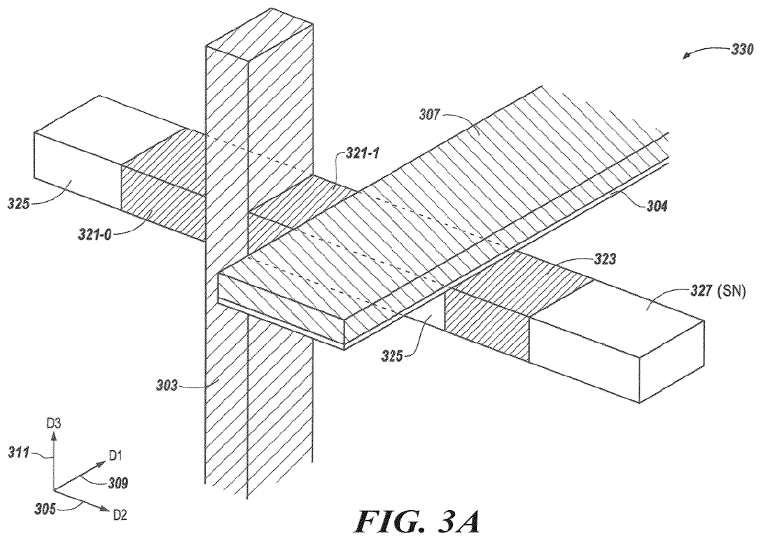

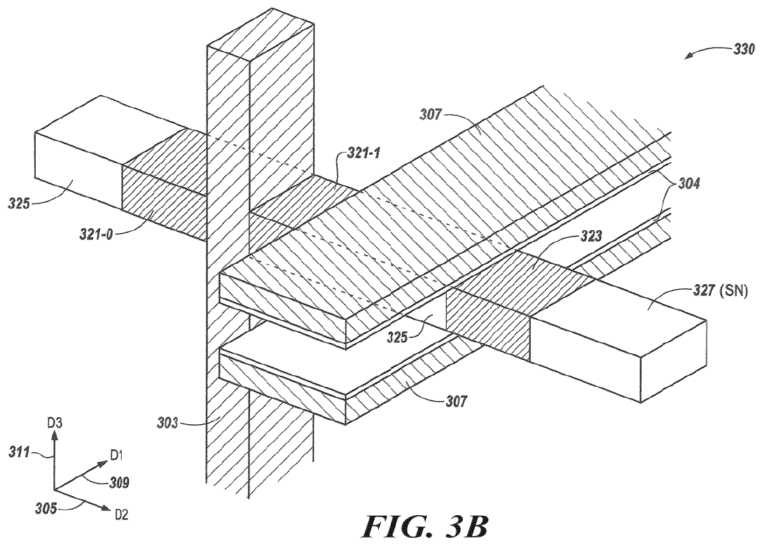

FIG. 3A illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 3A, the first and the second source/drain regions, 321 and 323, may be impurity doped regions to the laterally oriented access devices 330, e.g., transistors. The first and the second source/drain regions, 321 and 323, may be analogous to the first and the second source/drain regions 221 and 223 shown in FIG. 2. The first and the second source/drain regions, 321 and 323, may be formed from n-type or p-type dopants. Embodiments are not so limited.

For example, for an n-type conductivity transistor construction the body region of the horizontally oriented access devices 330, e.g., transistors, may be formed of a low doped p-type (p−) semiconductor material or intrinsic undoped semiconductor material. In one embodiment, the body region and the channel region 325 separating the first and the second source/drain regions, 321 and 323, may include a low doped, p-type (e.g., low dopant concentration (p−)) polysilicon material consisting of boron (B) atoms as an impurity dopant to the polycrystalline silicon. The first and the second source/drain regions, 321 and 323, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 321 and 323, may include a high dopant concentration, n-type conductivity impurity (e.g., high dopant (n+)) doped in the first and the second source/drain regions, 321 and 323. In some embodiments, the high dopant, n-type conductivity first and second drain regions 321 and 323 may include a high concentration of phosphorus (P) atoms deposited therein. Embodiments, however, are not limited to this example. In other embodiments, the horizontally oriented access devices 330, e.g., transistors, may be of a p-type conductivity construction in which case the impurity, e.g., dopant, conductivity types could be reversed.

The gate dielectric material 304 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 3A, a shared sense line, e.g., 303, analogous to the shared sense lines 203-1, 203-2, . . . , 203-Q in FIG. 2 and 103-1, 103-2, . . . , 103-Q in FIG. 1, may be vertically extending in the third direction (D3) 311 adjacent the first source/drain region 321 in the body to the horizontally oriented access devices 330, e.g., transistors horizontally conducting between the first and the second source/drain regions 321 and 323 along the second direction (D2) 305.

FIG. 3B illustrates a unit cell, e.g., memory cell 110 in FIG. 1, of the vertically stacked array of memory cells, e.g., within a sub cell array 101-2 in FIG. 1 having a dual gate horizontal access device structure. As shown in FIG. 3B, the first and the second source/drain regions, 321 and 323, may be impurity doped regions to the horizontally oriented access devices 330, e.g., transistors. The first and the second source/drain regions, 321 and 323, may be analogous to the first and the second source/drain regions 221 and 223 shown in FIG. 2 and the first and the second source/drain regions 321 and 323 shown in FIG. 3A. The first and the second source/drain regions 321 and 323 may be separated by a channel region 325 formed in a body of semiconductor material, e.g., body region, of the horizontally oriented access devices 330, e.g., transistors. The first and the second source/drain regions, 321 and 323, may be formed from n-type or p-type dopants. Embodiments are not so limited.

As shown in the example embodiment of FIG. 3B, a shared sense line, e.g., 303, analogous to the shared sense lines 203-1, 203-2, . . . , 203-Q in FIGS. 2 and 103-1, 103-2, . . . , 103-Q in FIG. 1, may be vertically extending in the third direction (D3) 311 adjacent the first source/drain region 321 in the body to the horizontally oriented access devices 330, e.g., transistors horizontally conducting between the first and the second source/drain regions 321 and 323 along the second direction (D2) 305.

FIG. 3B shows an example embodiment having a dual gate structure wherein the horizontally oriented access devices 330 are formed with the conductive gate material having a top portion above the channel region 325 and a bottom portion below the channel region 325 of the semiconductor material. In one embodiment, the horizontally oriented access devices 330 may be formed as gate all around (GAA) horizontal access devices with the conductive gate material fully around every surface of the channel region 325 formed in the body of the semiconductor material.

FIG. 4 is a cross-sectional view of an array of memory cells in accordance with a number of embodiments of the present disclosure. FIG. 4 includes a sub cell array 401, which can include one or more local sense lines (digit lines) 428-1, . . . , 428-N (individually or collectively referred to as local sense lines 428), one or more bleeder devices 424-1, . . . , 424-N (individually or collectively referred to as bleeder devices 424), one or more bleeder supplies 432, one or more sense line multiplexors 426-1, 426-2, . . . , 426-N (individually or collectively referred to as sense line multiplexors 426), one or more global sense line 434, and one or more sense amplifiers (sense amps) 438.

Further, FIG. 4 includes one or more plurality of capacitors 412-1, 412-2, 412-3, 412-4, . . . , 412-N (individually or collectively referred to as capacitors 412) coupled to one or more plate region 420-1, 420-2, . . . , 420-N (individually or collectively referred to as plate regions 420), a bias voltage supply 436, e.g. a plate, and one or more plurality of access devices 416-1, 416-2, 416-3, 416-(N−1), . . . , 416-N (individually or collectively referred to as access devices 416). In some embodiments, a plate region 420 can be coupled to a first side of a capacitor 412 and an access device 416 can be coupled to a second side of the capacitor 412 that is opposite of the first side of the capacitor 412. Each coupling of a capacitor 412 and an access device 416 can form a memory cell (e.g., memory cell 110 in FIG. 1). Each memory cell can be coupled to a local sense line 428.

Each global sense line 434 can be coupled to a respective sense amp 438. Further, each global sense line 434 can be coupled to one or more local sense lines 428. In some embodiments, each local sense line 428 can be coupled to a global sense line 434 via a sense line multiplexor 426. In some embodiments, a driver (not pictured) can be coupled to the global sense line 434. The driver can be configured to drive current to a local sense line 428 via the global sense line 434 to select a memory cell (e.g., memory cell 110 of FIG. 1) of a stack of memory cells coupled to the local sense line 428.

In some embodiments, each plate region 420 can be coupled to the plate bias voltage supply 436. In some embodiments, the plate bias voltage supply 436 can be configured to drive a voltage of the plate region 420 to the same value as the voltage of the plate bias voltage supply 436. In some embodiments, the voltage of the bias voltage supply plate 436 can be chosen to minimize leakage from a capacitor 412 of a memory cell.

In some embodiments, each local sense line 428 can be coupled to a first end of a respective bleeder device 424 and the bleeder supply 432 can be coupled to a second end of each bleeder device 424. In some embodiments, the bleeder supply 432 and the plate bias voltage supply 436 are separate voltage supplies, in other embodiments, the bleeder supply 432 and the plate bias voltage supply 436 can be the same voltage supply. In some embodiments, the bleeder device 424 can be configured to drive a voltage of a local sense line 428 coupled to the bleeder device 424 to the same value as the voltage (bleeder supply voltage) of the bleeder supply 432. In some embodiments, a magnitude of the bleeder supply 432 voltage can be a magnitude of voltage of a local sense line 428 that decreases leakage current in an access device 416 of the memory cell coupled to the local sense line 428 when the memory cell is in an idle state. In some embodiments, the bleeder supply 432 voltage can be selected to decrease the leakage current of an access device 416 of a memory cell when the memory cell is in a low (e.g., zero) state. In some embodiments, the magnitude of the voltage of the local sense line 428 that decreases the leakage current of the access device 416 can be 100 millivolts (mV). In some embodiments, the voltage of the bleeder supply 432 can be different than the voltage of the plate bias voltage supply 436. In some embodiments, the bleeder supply 432 can be connected to an edge of a sub cell array 401 of memory cells. In some embodiments, a magnitude of the voltage of the bias voltage supply 436 and a magnitude of the voltage of the bleeder supply 432 can be selected to reduce the leakage current of an access device 416. In a non-limiting example, magnitudes of the voltages of the bleeder supply and the plate bias voltage supply can be selected to reduce the leakage current of a access device 416 when the memory cell is in a low data state For example, the bias voltage supply 436 can be a plate with a voltage of 0.5 V, and the bleeder device 424 can be a multiplexor connected to a bleeder supply 432, that is separate from the plate bias voltage supply 436, at the edge of the array with a voltage of 100 mV.

The memory device can be configured such that a magnitude of the voltage of the global sense line 434 is different than the magnitude of the voltage of the local sense line 428 when the sense line multiplexor 426 is deactivated (e.g., turned off). In some embodiments, the sense amp 438 can sense the voltage of the global sense line 434 and latch the sensed voltage of the global sense line 434 at 0 volts (V) or 1 V when the sense line multiplexor 426 is activated. The sense line multiplexor 426 can then be deactivated and the voltage of the local sense line 428 can then be driven to the voltage of the bleeder supply 432 by the activation of the bleeder device 424 while the voltage of the global sense line 434 remains unchanged. Therefore, when the local sense line 428 is idle (e.g., the sense line multiplexor is turned off and the bleeder device is turned on), the global sense line 434 and local sense line 428 can have different voltages. The different voltages can result from the global sense line 434 and the local sense line 428 being biased separately by the sense amplifier 438 and the bleeder supply 432, respectively.

The memory device can be configured such that a voltage of the bleeder supply 432 is equal to (substantially equal to) a value that reduces leakage current in an access device 416 when the local sense line 428 is in an idle state. In some embodiments, the bleeder supply 432 voltage can be selected to minimize leakage current of an access device 416 in a low voltage state or a high voltage state when the local sense line 428 to which the access device 416 is coupled is in an idle state. The body of the access device 416 can be discharged when the local sense line 428 is in an idle state. Embodiments are not so limited.

In some embodiments, the memory device can be configured such that the memory device includes a circuit to detect a temperature of the capacitor 412 or other component of the memory device. The memory device can further be configured such that the bleeder supply voltage changes based on the detected temperature of the capacitor 412. For example, a circuit, such as a bandgap temperature sensor, can be used to detect a temperature of the memory device and the voltage of the bleeder supply 432 can be changed to minimize the voltage leakage of the access device 416 (e.g., transistor) at the detected temperature.

In some embodiments, the memory device can be configured such that the voltage of the bleeder supply 432 can change based on characteristics of the access device 416, in order to minimize leakage current. The characteristics of the access device 416 can include, but are not limited to, materials used to form the access device 416, dimensions of the access device 416, deposition techniques used to form the access device 416, or any combination thereof. The bleeder supply 432 can be configured to operate at a bleeder supply voltage. The bleeder supply voltage can be selected to reduce the leakage current in an access device 416 and can vary based on a type of silicon, process requirements, a function of temperature, or other characteristics of the access device 416.

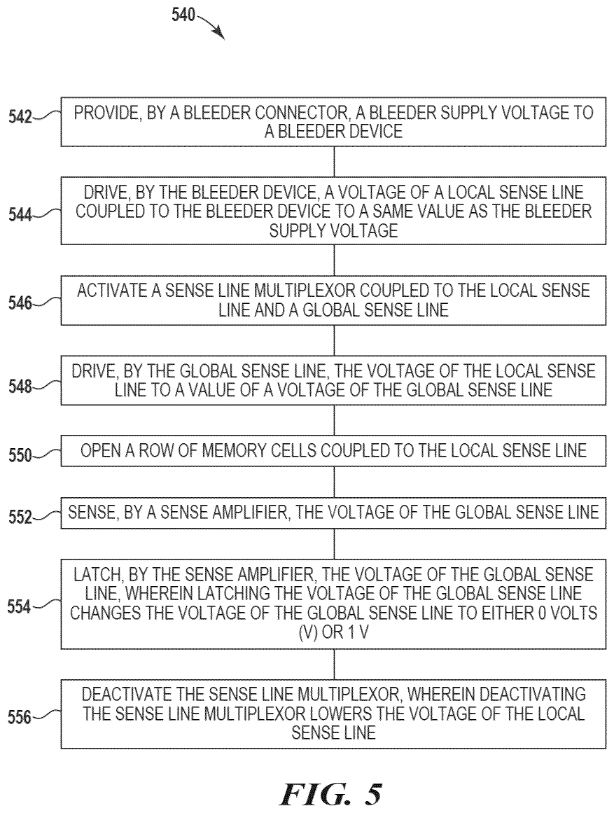

FIG. 5 is a flow diagram corresponding to a method 540 for discharging a transistor in a memory device in accordance with a number of embodiments of the present disclosure. The method 540 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 542, the method 540 can include providing, by a bleeder connector (e.g., bleeder supply 432 of FIG. 4), a bleeder supply voltage to a bleeder device (e.g., bleeder device 424 of FIG. 4). In some embodiments, the bleeder supply voltage can be selected to minimize a leakage current of an access device when the memory cell is in a low voltage state or a high voltage state. As stated previously, the bleeder supply can have a voltage of 100 millivolts to minimize the leakage current of a memory cell in a low voltage state or a high voltage state. In some embodiments, the bleeder device can include a multiplexor connecting a local sense line (e.g., local sense line 428 of FIG. 4) to the bleeder supply.

At block 544, the method 540 can include driving, by the bleeder device, a voltage of a local sense line (e.g., local sense line 428 of FIG. 4) coupled to the bleeder device to a same value as the bleeder supply voltage. In some embodiments, the bleeder device can drive the bleeder supply voltage to a value that minimizes leakage in an access device when the memory cell is in a low voltage state or a high voltage state. For example, the bleeder device can drive the voltage of the local sense line to a voltage of equal to or substantially equal to 100 mV. In some embodiments, the bleeder device can drive the voltage of the local sense line to the same value as the bleeder supply voltage before a sense amplifier is activated.

At block 546, the method 540 can include activating a sense line multiplexor (e.g., sense line multiplexor 426 of FIG. 4) coupled to the local sense line (e.g., local sense line 428 of FIG. 4) and the global sense line (e.g., global sense line 434 of FIG. 4). In some embodiments, the bleeder device (e.g., bleeder device 424 of FIG. 4) can be deactivated before the sense line multiplexor is activated (e.g., turned on).

At block 548, the method 540 can include driving, by the global sense line, the voltage of the local sense line (e.g., local sense line 428 of FIG. 4) to (or substantially to) a voltage of the global sense line. In some embodiments, the sense amp can sense a difference in voltage of the global sense line after the global sense line applies voltage to the local sense line. Further, in some embodiments the voltage of the global sense line may have been latched by a sense amp at a magnitude of 0 V or 1 V.

At operation 550, the method 540 can include opening a row of memory cells (e.g., memory cells 110 of FIG. 1) coupled to the local sense line (e.g., local sense line 428). In some embodiments, the memory cells can be opened as a result of the memory cells receiving an activate command from a host. The row of memory cells can remain open while data is stored in the sense amp and until the data is written to the open row or sensed by the sense amp. In some embodiments, the capacitor opening the memory cells may dump the charge of the capacitor of the memory device onto the local sense line, and the global sense line when the sense line multiplexor is activated. A voltage of the local sense line can be less than the bias supply voltage when memory cells coupled to the local sense line are not being accessed and the voltage of the local sense line can be greater than or equal to the bias supply voltage when the memory cell is being accessed (e.g., a memory operation is being performed on the memory cell).

At block 552, the method 540 can include sensing, by a sense amplifier (e.g., sense amplifier 438 of FIG. 4), the voltage of the global sense line (e.g., global sense line 434 of FIG. 4). In some embodiments, the sensed voltage of the global sense line is the change in the voltage of the global sense line after the access line goes high. In some embodiments, the sense amplifier can compare the sensed voltage of the global sense line to a reference voltage of a reference global sense line.

At block 554, the method 540 can include latching, by the sense amp, the voltage of the global sense line, wherein latching the voltage of the global sense line changes the voltage of the global sense line to either 0 V or 1 V. In some embodiments, the latched voltage is based on the sensed voltage of the global sense line, the change in sensed voltage of the global sense line, or the comparison of the sensed voltage of the global sense line to a sensed voltage of a reference global sense line.

At block 556, the method 540 can include deactivating the sense line multiplexor, wherein deactivating the sense line multiplexor lowers the voltage of the local sense line. In some embodiments, the voltage of the local sense line can be lowered to the bleeder supply (e.g., bleeder supply 432 of FIG. 4) voltage via the activation of the bleeder device (e.g., bleeder device 424 of FIG. 4). For example, the voltage of the local sense line can be lowered to 100 mV in response to sense line multiplexor being deactivated. The voltage of the global sense line after the sense line multiplexor is deactivated can be determined based on an amount of the change in the voltage of the global sense line from a first time prior to the global sense line applying the voltage to the local sense and a second time after the global sense line applies the voltage to the local sense line.

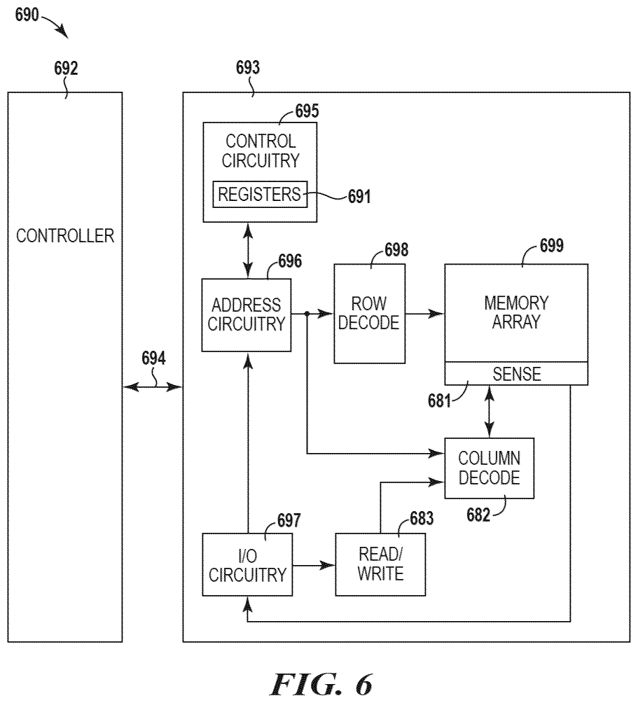

FIG. 6 is a block diagram of an apparatus in the form of a computing system 690 including a memory device 693 in accordance with a number of embodiments of the present disclosure. As used herein, a memory device 693, a memory array 699, and/or a host (e.g., controller) 692, for example, might also be separately considered an “apparatus.” According to embodiments, the memory device 693 may comprise at least one memory array 699 having an access device for vertical three-dimensional (3D) memory, as has been described herein.

In this example, system 690 can include a host 692 coupled to memory device 693 via an interface 694. The computing system 690 can be a personal laptop computer, a desktop computer, a digital camera, a mobile telephone, a memory card reader, or an Internet-of-Things (IoT) enabled device, among various other types of systems. A host device or host 692 can include a number of processing resources (e.g., one or more processors, microprocessors, or some other type of controlling circuitry) capable of accessing memory device 693. The system 690 can include separate integrated circuits, or both the host 692 and the memory device 693 can be on the same integrated circuit. For example, the host 692 may be a system controller of a memory system comprising multiple memory devices 693, with the control circuitry (e.g., system controller) 695 providing access to the respective memory devices 693 by another processing resource such as a central processing unit (CPU).

In the example shown in FIG. 6, the host 692 can be responsible for executing an operating system (OS) and/or various applications (e.g., processes) that can be loaded thereto (e.g., from memory device 693 via system controller 695). The OS and/or various applications can be loaded from the memory device 693 by providing access commands from the host 692 to the memory device 693 to access the data comprising the OS and/or the various applications. The host 692 can also access data utilized by the OS and/or various applications by sending access commands to the memory device 693 to retrieve said data utilized in the execution of the OS and/or the various applications.

For clarity, the system 690 has been simplified to focus on features with particular relevance to the present disclosure. The memory array 699 can be a DRAM array, SRAM array, STT RAM array, PCRAM array, TRAM array, RRAM array, NAND flash array, and/or NOR flash array, comprising at least one access device for three dimension (3D) memory. For example, the memory array 699 can be an unshielded DL 4F2 array such as a 3D-DRAM memory array. The array 699 can comprise memory cells arranged in rows coupled by access lines and columns coupled by sense lines. Although a single array 699 is shown in FIG. 6, embodiments are not so limited. For instance, memory device 693 may include a number of arrays 699 (e.g., a number of banks of DRAM cells).

The memory device 693 can include address circuitry 696 to latch address signals provided over an interface 694. The interface can include, for example, a physical interface employing a suitable protocol (e.g., a data bus, an address bus, and a command bus, or a combined data/address/command bus). Such protocol may be custom or proprietary, or the interface 694 may employ a standardized protocol, such as Peripheral Component Interconnect Express (PCIe), Gen-Z, CCIX, or the like. Address signals are received and decoded by a row decoder 698 and a column decoder 682 to access the memory array 699. Data can be read from memory array 699 by sensing voltage and/or current changes on the sense lines using sensing circuitry 681. The sensing circuitry 681 can comprise, for example, sense amplifiers that can read and latch a page (e.g., row) of data from the memory array 699. The I/O circuitry 697 can be used for bi-directional data communication with the host 692 over the interface 694. The read/write circuitry 683 can be used to write data to the memory array 699 or read data from the memory array 699. As an example, the circuitry 683 can comprise various drivers, latch circuitry, etc.

Control circuitry 695 can decode signals provided by the host 692. The signals can be commands provided by the host 692. These signals can include chip enable signals, write enable signals, and address latch signals that are used to control operations performed on the memory array 699, including data read operations, data write operations, and data erase operations. In various embodiments, the control circuitry 695 can be responsible for executing instructions from the host 692. The control circuitry 695 can comprise a state machine, a sequencer, registers 691, and/or some other type of control circuitry, which may be implemented in the form of hardware, firmware, or software, or any combination of the three. In some examples, the host 692 can be a controller external to the memory device 693. For example, the host 692 can be a memory controller which can be coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A memory device, comprising:
a local sense line;
a bleeder device coupled to the local sense line and a bleeder supply;
a sense line multiplexor coupled to the local sense line and a global sense line;
a sense amplifier coupled to the global sense line and configured to sense and latch a voltage of the global sense line in response to the memory device receiving a command;
a plurality of access devices coupled to the local sense line;
a plurality of capacitors coupled to the plurality of access devices; and
a plate voltage supply, separate from the bleeder supply, coupled to the plurality of capacitors.

2. The memory device of claim 1, wherein a voltage of the global sense line is different than the voltage of the local sense line when the sense line multiplexor is deactivated.

3. The memory device of claim 1, wherein the bleeder device is configured to operate at a bleeder supply voltage, wherein the bleeder supply voltage is a voltage that reduces leakage current in an access transistor when the local sense line is in an idle state.

4. The memory device of claim 3, wherein the memory device includes a circuit to detect a temperature of the capacitor.

5. The memory device of claim 4, wherein the bleeder supply voltage changes based on the detected temperature of the capacitor.

6. The memory device of claim 3, wherein the bleeder supply voltage changes based on characteristics of the access transistor.

7. The memory device of claim 6, wherein the characteristics of the access transistor include materials used to form the access transistor, dimensions of the access transistor, deposition techniques used to form the access transistor, or any combination thereof.

8. The memory device of claim 1, wherein a bleeder supply voltage supply is different from a voltage of the plate voltage supply.

9. The memory device of claim 1, wherein the bleeder supply is connected to an edge of an array of memory cells.

10. A method, comprising:
providing by a bleeder connector, a bleeder supply voltage to a bleeder device;
driving, by the bleeder device, a voltage of a local sense line coupled to the bleeder device to a same value as the bleeder supply voltage;
activating a sense line multiplexor coupled to the local sense line and a global sense line;
driving, by the global sense line, the voltage of the local sense line to a value of a voltage of the global sense line;
opening a row of memory cells coupled to the local sense line;
sensing, by a sense amplifier, the voltage of the global sense line;
latching, by the sense amplifier, the voltage of the global sense line, wherein latching the voltage of the global sense line changes the voltage of the global sense line to either 0 volts (V) or 1 V; and
deactivating the sense line multiplexor, wherein deactivating the sense line multiplexor lowers the voltage of the local sense line.

11. The method of claim 10, further comprising lowering the voltage of the local sense line to 100 millivolts in response to deactivating the sense line multiplexor.

12. The method of claim 10, further comprising applying, by the global sense line, a voltage to the local sense line when the sense line multiplexor is activated.

13. The method of claim 12, further comprising sensing, by the sense amplifier, a difference in the voltage of the global sense line after the global sense line applies the voltage to the local sense line.

14. The method of claim 13, further comprising, determining the voltage of the global sense line after the sense line multiplexor is activated based on an amount of change in the voltage of the global sense line between a first time prior to the global sense line applying the voltage to the local sense line and a second time after the global sense line applies the voltage to the local sense line.

15. The method of claim 10, further comprising decreasing an amount of leakage in an access transistor coupled to the local sense line when a memory cell that includes the access transistor is in a low data state or a high data state.

16. The method of claim 10, further comprising discharging a body of an access device coupled to the local sense line when the local sense line is idle.

17. A system, comprising:
a host device configured to send a command; and
a memory device, comprising:
a local sense line;
a bleeder device coupled to the local sense line and a bleeder supply;
a sense line multiplexor coupled to the local sense line and a global sense line;
a sense amplifier coupled to the global sense line and configured to sense and latch a voltage of the global sense line in response to the memory device receiving the command from the host device;
a plurality of access devices coupled to the local sense line;
a plurality of capacitors coupled to the plurality of access devices; and
a bias voltage supply, separate from the bleeder supply, coupled to the plurality of capacitors.

18. The system of claim 17, wherein a connection to the bleeder supply is disposed at an edge of an array of the memory device.

19. The system of claim 17, wherein the bleeder device is a multiplexor coupling the local sense line to the bleeder supply.

20. The system of claim 17, wherein:
a voltage of the local sense line is less than a voltage of the plate voltage supply when memory cells coupled to the local sense line are not being accessed; and
the voltage of the local sense line is greater than or equal to the voltage of the plate voltage supply when at least one of the memory cells coupled to the local sense line is being accessed.
